(19) United States
(12) Patent Application Publication
(10) Pub. No.: US 2009/0229525 A1
(43) Pub. Date: Sep. 17, 2009

(54) VAPORIZER AND FILM FORMING APPARATUS

(75) Inventor: Takashi MOCHIZUKI, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Minato-ku (JP)

(21) Appl. No.: 12/426,121

(22) Filed: Apr. 17, 2009

Related U.S. Application Data
(63) Continuation of application No. PCT/JP07/65344, filed on Aug. 6, 2007.

(30) Foreign Application Priority Data
Oct. 18, 2006 (JP) 2006-283281

(51) Int. Cl. C23C 16/448; B05B 7/08

(52) U.S. Cl. 118/726; 239/418

(57) ABSTRACT

The size of drops of liquid raw material spouted into a vaporization chamber is controlled so as to suppress any dispersion of drop size, thereby attaining assured vaporization of the drops. The vaporizer comprises raw material liquid chamber 410 into which a liquid raw material is fed at given pressure; multiple raw material spout nozzles 420 for spouting the liquid raw material stored in the raw material liquid chamber; vaporization chamber 430 for vaporizing the liquid raw material spouted from the multiple raw material spout nozzles so as to form a source gas; and piezoelectric device 440 for periodically changing the volume of internal space of the raw material liquid chamber so as to apply spout pressure to the liquid raw material.

This application is a Continuation Application of PCT International Application No. PCT/JP2007/065344 filed on Aug. 6, 2007, which designated the United States.

### FIELD OF THE INVENTION

The present invention relates to a vaporizer that vaporizes a liquid raw material to generate a source gas and a film forming apparatus including the vaporizer.

### BACKGROUND OF THE INVENTION

Generally, a chemical vapor deposition (CVD) method is known as a method for forming various thin films made of a dielectric, metal, semiconductor or the like. In the CVD method, an organic source gas, such as an organic metal compound gas, is supplied into a film forming chamber and reacts with another gas, such as oxygen or ammonia, to form a film. An organic raw material used in the CVD method is normally liquid or solid at room temperature. Accordingly, a vaporizer for vaporizing the organic raw material is needed. For example, the organic raw material is generally diluted or dissolved by using a solvent into a liquid raw material. The liquid raw material is sprayed from a spraying nozzle provided at the vaporizer into a heated vaporization chamber along with, e.g., a carrier gas to thereby produce a source gas. The source gas is supplied into the film forming chamber and reacts with another gas to form a film on a substrate (see, e.g., Patent Documents 1 to 3).

In such a conventional vaporizer, most of the liquid raw material sprayed from the spraying nozzle is vaporized in the vaporization chamber. However, some of the liquid raw material continues to float in the vaporization chamber without being vaporized. In the meantime, only the solvent volatilizes, and the floating liquid raw material may become fine particles. The particles accumulate in the spraying nozzle, the inner wall of the vaporization chamber, a filter, the inside of a gas transport pipe, and the like to thereby cause clogging of these portions. Further, the particles may reach the film forming chamber along with the source gas, thereby causing abnormal film formation or poor film quality. From the past, various measures have been taken to solve such problems (see, e.g., Patent Documents 4 to 7).

Patent Document 4 discloses a technique for enabling long-distance movement of liquid droplets ejected from a spraying nozzle in a vaporization chamber having a shape extending in the droplet ejection direction of the spraying nozzle, so that the liquid droplets are sufficiently heated by radiation from the inner wall of the vaporization chamber. Further, Patent Document 5 discloses a scheme for forming a plurality of protrusions at the inner wall of a vaporization chamber to secure a region where no liquid droplets are attached. In this case, it is possible to suppress the extreme reduction in amount of heat supplied from the wall of the vaporization chamber, thereby stably maintaining the vaporization efficiency. Further, Patent Document 6 discloses a technique for providing a vaporizer with a vaporization surface made of a porous material to increase the probability for the liquid droplets to be contact with the vaporization surface, thereby improving the vaporization efficiency and suppressing the generation of particles.

Patent Document 1: Japanese Patent Laid-open Application No. H3-126872

Patent Document 2: Japanese Patent Laid-open Application No. H6-310444

Patent Document 3: Japanese Patent Laid-open Application No. H7-94426

Patent Document 4: Japanese Patent Laid-open Application No. 2005-228889

Patent Document 5: Japanese Patent Laid-open Application No. 2006-135053

Patent Document 6: Japanese Patent Laid-open Application No. 2005-109349

Patent Document 7: Japanese Patent Laid-open Application No. S60-22065

In the above-mentioned conventional vaporizer, liquid droplets of the liquid raw material discharged from the single nozzle are ejected into the vaporization chamber along with the flow of the carrier gas. Accordingly, the sizes of the liquid droplets floating in the vaporization chamber may differ from one another according to the mixed state of the carrier gas and the liquid raw material. That is, in the conventional vaporizer in which the liquid raw material is discharged from only the single nozzle, it is difficult to control the size or direction of the discharged liquid droplets only by controlling the discharge amount of the liquid raw material. Also, the sizes of the discharged liquid droplets may differ from one another, or the discharged liquid droplets may combine into large-sized liquid droplets.

When the large-sized liquid droplets are formed in the conventional vaporizer as described above, the large-sized liquid droplets are not completely vaporized in the vaporization chamber, and some of the large-sized liquid droplets may reach a wafer in a film forming chamber, and may become so-called mist particles, which may be attached to the surface of the wafer.

Also, the large-sized liquid droplets not completely vaporized in the vaporization chamber are attached to the wall of the vaporization chamber, and are thermally decomposed while remaining there for a long time. The resultant thermally decomposed products may peel off the wall of the vaporization chamber, and may be forwarded into the film forming chamber. In the film forming chamber, the thermally decomposed products may become so-called residual particles, which may be scattered on the wafer.

In this aspect, Patent Document 7 suggests that liquid droplets of a liquid fuel are injected from the front end of the nozzle, while the discharge pressure is changed by a piezoelectric vibrator, to reduce the size of the liquid droplets. Even in this case, the fuel is ejected only from the single nozzle and, thus, it is actually difficult to further minutely control the size or direction of the discharged liquid droplets only by controlling the discharge amount of the liquid raw material. Further, Patent Document 7 relates to a fuel injector to supply a fuel to an engine, which is different from a vaporizer used in a film forming apparatus. Accordingly, required size or flow rate of the liquid droplets is quite different, and a technology of the fuel injector is not applicable as it is.

### SUMMARY OF THE INVENTION

The present invention is devised in view of the above-mentioned problems. An object of the present invention is to provide a vaporizer capable of forming fine liquid droplets having a uniform size from a liquid raw material and surely vaporizing the liquid droplets to generate a source gas of good quality containing no particles, and a film forming apparatus including the vaporizer.

In accordance with an aspect of the present invention, there is provided a vaporizer comprising: a raw material liquid chamber into which a liquid raw material is supplied at a predetermined pressure; discharge ports for discharging the liquid raw material stored in the raw material liquid chamber; a vaporization chamber for vaporizing the liquid raw material discharged from the discharge ports to generate a source gas; and a pressurizing unit for periodically changing a volume of an inner space of the raw material liquid chamber to apply a discharge pressure to the liquid raw material.

In accordance with another aspect of the present invention, there is provided a film forming apparatus comprising: a raw material supply system for supplying a liquid raw material; a vaporizer for vaporizing the liquid raw material to generate a source gas; and a film forming chamber into which the source gas is introduced from the vaporizer, the film forming chamber being configured to perform a film forming process on a substrate to be processed, wherein the vaporizer includes: a raw material liquid chamber into which a liquid raw material is supplied at a predetermined pressure; discharge ports for discharging the liquid raw material stored in the raw material liquid chamber; a vaporization chamber for vaporizing the liquid raw material discharged from the discharge ports to generate a source gas; and a pressurizing unit for periodically changing a volume of an inner space of the raw material liquid chamber to apply a discharge pressure to the liquid raw material.

In accordance with the vaporizer and the film forming apparatus, a plurality of the discharge ports configured to discharge a liquid raw material into the raw material liquid chamber are provided and, therefore, it is possible to uniformalize the size of liquid droplets discharged from the respective discharge ports in the direction perpendicular to the discharge direction thereof. Also, it is possible to control the size of liquid droplets in the direction perpendicular to the discharge direction thereof to be further reduced, only by reducing the diameter of the respective discharge ports. Consequently, it is possible to discharge fine liquid droplets having a uniform size from the respective discharge ports.

Further, the discharge amounts of the liquid droplets discharged from the respective discharge ports are uniformalized by periodically changing the volume of the inner space of the raw material liquid chamber. Accordingly, it is also possible to uniformalize the size of the liquid droplets discharged from the respective discharge ports in the discharge direction thereof. Also, it is possible to control the size of liquid droplets in the discharge direction thereof to be further reduced by further shortening the volume changing period while reducing the change amount of the volume of the inner space of the raw material liquid chamber. Consequently, it is possible to discharge further fine liquid droplets having a uniform size from the respective discharge ports.

Such liquid droplets are reliably vaporized in the vaporization chamber. Consequently, it is possible to generate a source gas of good quality containing no particles. Also, it is possible to continuously discharge fine liquid droplets having a uniform size from the respective discharge ports and, therefore, it is possible to generate a sufficient amount of the source gas.

A diameter of each of the discharge ports may be set according to a target size of liquid droplets of the liquid raw material discharged into the vaporization chamber. Accordingly, it is possible to accurately control the size of the liquid droplets in the direction perpendicular to the discharge direction thereof according to the diameter of the discharge ports. Consequently, it is possible to uniformalize the size of the liquid droplets discharged from the respective discharge ports.

Further, when the diameter of the respective discharge ports is set to be 20 μg or less, it is possible to form fine liquid droplets having a uniform size without vaporization defects.

The discharge ports may be disposed such that discharge directions of the liquid raw material are parallel to one another, and uniformly arranged in a plane direction perpendicular to the discharge directions of the liquid raw material. In a structure in which respective discharge ports are disposed as described above, the liquid droplets discharged from the respective discharge ports are vaporized without combining with each another during the flight in the vaporization chamber. Consequently, it is possible to prevent the generation of particles.

An area where the discharge ports are arranged may be set according to an area of the vaporization chamber in the plane direction. Accordingly, the liquid droplets discharged from the respective discharge ports are supplied over the whole area in the vaporization chamber. Consequently, the respective liquid droplets can be reliably vaporized without combining with each another.

In accordance with the above-described vaporizer, the liquid droplets of the liquid raw material discharged from the respective discharge ports can be satisfactorily dropped by vibrating the flexible member using the vibration unit and thus periodically applying discharge pressure to the liquid raw material in the raw material liquid chamber. Therefore, it is possible to control the size of the liquid droplets in the discharge direction thereof to be further uniformalized. Also, finer control of the size of the liquid droplets in the discharge direction thereof can be made by controlling the vibration frequency and amplitude. Since the size of the liquid droplets is controlled such that the size of the liquid droplets further decreases and is uniformalized, as described above, it is possible to reliably vaporize the liquid droplets in the vaporization chamber. Consequently, it is possible to generate a source gas of good quality containing no particles. Also, it is possible to continuously discharge fine liquid droplets having a uniform size from the respective discharge ports and, therefore, it is possible to generate a sufficient amount of the source gas.

The vibration unit may include a piezoelectric element. Further, an amplitude of the vibration unit may be set according to the number of the raw material discharge nozzles and a target size of liquid droplets of the liquid raw material discharged into the vaporization chamber. Further, a vibration period of the vibration unit may be set according to a target number of liquid droplets of the liquid raw material discharged into the vaporization chamber per unit time.

In accordance with still another aspect of the present invention, there is provided a vaporizer comprising: a raw material liquid chamber into which a liquid raw material is supplied at a predetermined pressure; discharge ports for discharging the liquid raw material stored in the raw material liquid chamber; a vaporization chamber vaporizing the liquid raw material discharged from the discharge ports to generate a source gas; a pressurizing unit for periodically changing a volume of an inner space of the raw material liquid chamber to apply a discharge pressure to the liquid raw material; and carrier gas ejection ports for ejecting a carrier gas to circumferences of the discharge ports.

In accordance with the aspects of the present invention, it is possible to discharge fine liquid droplets having a uniform size from the respective discharge ports by periodically minutely changing the volume of the inner space of the raw material liquid chamber. Such liquid droplets can be reliably vaporized in the vaporization chamber. Also, it is possible to eject the carrier gas from the circumferences of the respective discharge ports. Consequently, it is possible to stabilize the flight of the liquid droplets discharged into the vaporization chamber and to reliably control the flow direction of the liquid droplets. Therefore, the liquid droplets can be vaporized without combining with each other. As a result, it is possible to generate a source gas of good quality containing no particles. Also, it is possible to continuously discharge fine liquid droplets having a uniform size from the respective discharge ports and, therefore, it is possible to generate a sufficient amount of the source gas.

Further, preferably, the number of the carrier gas ejection ports is equal to that of the discharge ports, and a diameter of the carrier gas ejection ports is greater than that of the discharge ports such that the discharge ports are disposed in the carrier gas ejection ports, respectively. Accordingly, it is possible to eject the carrier gas from the circumferences of the respective discharge ports.

Further, preferably, the number of the carrier gas ejection ports is greater than that of the discharge ports such that a plurality of the carrier gas ejection ports are disposed around each of the discharge ports. Accordingly, it is possible to eject the carrier gas from the circumferences of the respective discharge ports.

In accordance with still another aspect of the present invention, there is provided a vaporizer comprising: a raw material liquid chamber into which a liquid raw material is supplied at a predetermined pressure; discharge ports for discharging the liquid raw material stored in the raw material liquid chamber; a vaporization chamber for vaporizing the liquid raw material discharged from the discharge ports to generate a source gas; a pressurizing unit for periodically changing a volume of an inner space of the raw material liquid chamber to apply a discharge pressure to the liquid raw material; and a draining port for draining the source gas from the vaporization chamber, wherein the vaporization chamber has guide holes for guiding liquid droplets of the liquid raw material discharged from the discharge ports toward the draining port, and wherein inlets of the guide holes face the discharge ports, respectively.

In accordance with the above-described vaporizer, it is possible to discharge fine liquid droplets having a uniform size from the respective discharge ports by periodically minutely changing the volume of the inner space of the raw material liquid chamber. Such liquid droplets can be reliably vaporized in the vaporization chamber. Also, the liquid droplets discharged from the respective discharge ports are introduced into the guide holes facing the discharge ports. Accordingly, the liquid droplets can be vaporized without combining with each other. As a result, it is possible to generate a source gas of good quality containing no particles. Also, it is possible to continuously discharge fine liquid droplets having a uniform size from the respective discharge ports and, therefore, it is possible to generate a sufficient amount of the source gas.

### EFFECTS OF THE INVENTION

In accordance with the aspects of the present invention, it is possible to form fine liquid droplets having a uniform size from a liquid raw material and reliably vaporize the liquid droplets, thereby generating a source gas of good quality containing no particles.

### BRIEF DESCRIPTION OF THE DRAWINGS

FIG. 1 is a block diagram illustrating a schematic configuration of a film forming apparatus in accordance with a first embodiment of the present invention.

FIG. 2 is a longitudinal cross sectional view illustrating a schematic configuration of a vaporizer in accordance with the first embodiment of the present invention.

FIG. 3 is a cross sectional view taken along the line III-III of the vaporizer shown in FIG. 2.

FIG. 4 is a perspective view illustrating an arrangement relationship between a raw material discharge nozzle and a carrier gas ejection port shown in FIG. 2.

FIG. 5 is a conceptional view illustrating a state when a liquid droplet is discharged from the front end of the raw material discharge nozzle in accordance with the first embodiment of the present invention.

FIG. 6 is a longitudinal cross sectional view illustrating a schematic configuration of a vaporizer in accordance with a second embodiment of the present invention.

FIG. 7 is a cross sectional view taken along the line VII-VII of the vaporizer shown in FIG. 6.

FIG. 8 is a longitudinal cross sectional view illustrating a schematic configuration of a vaporizer in accordance with a third embodiment of the present invention.

FIG. 9 is a sectional view taken along the line IX-IX of the vaporizer shown in FIG. 8.

FIG. 10 is a perspective view illustrating an arrangement relationship between a raw material discharge nozzle and a plurality of carrier gas ejection ports located around the raw material discharge nozzle shown in FIG. 8.

FIG. 11 is a conceptional view illustrating a state when a liquid droplet is discharged from the front end of the raw material discharge nozzle in accordance with the third embodiment of the present invention.

### DETAILED DESCRIPTION OF THE EMBODIMENTS

Hereinafter, embodiments of the present invention will be described in detail with reference to the accompanying drawings which form a part hereof. In the specification and drawings, elements substantially having the same functions and constructions are denoted by the same reference numerals to omit a redundant description.

(Film Forming Apparatus of First Embodiment)

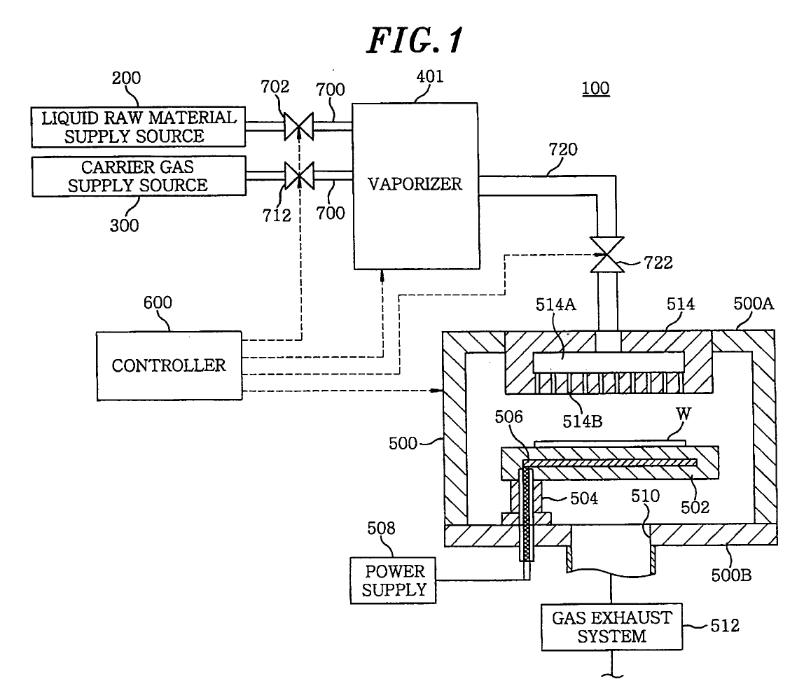

First, a film forming apparatus in accordance with a first embodiment of the present invention will be described with reference to FIG. 1. FIG. 1 is a block diagram illustrating a schematic configuration of a film forming apparatus 100 in accordance with the first embodiment of the present invention. The film forming apparatus 100 is an apparatus which forms, e.g., a hafnium (Hf) oxide film, on a substrate to be processed, e.g., a semiconductor wafer (hereinafter, simply referred to as a ‘wafer’) W by a CVD method. The film forming apparatus 100 includes a liquid raw material supply source 200 for supplying a liquid raw material including Hf, a carrier gas supply source 300 for supplying a carrier gas, a vaporizer 401 for vaporizing the liquid raw material supplied from the liquid raw material supply source 200 to generate a source gas, a film forming chamber 500 for forming a Hf oxide film on a wafer W using the source gas generated by the vaporizer 401, and a controller 600 for controlling the respective components of the film forming apparatus 100.

The liquid raw material supply source 200 and the vaporizer 401 are connected to each other via a liquid raw material supply pipe 700. The carrier gas supply source 300 and the vaporizer 401 are connected to each other via a carrier gas supply pipe 710. The vaporizer 401 and the film forming chamber 500 are connected to each other via a source gas supply pipe 720. The liquid raw material supply pipe 700 is provided with a liquid raw material flow rate control valve 702. The carrier gas supply pipe 710 is provided with a carrier gas flow rate control valve 712. The source gas supply pipe 720 is provided with a source gas flow rate control valve 722. Opening degrees of the liquid raw material flow rate control valve 702, the carrier gas flow rate control valve 712, and the source gas flow rate control valve 722 are adjusted according to control signals from the controller 600. The controller 600 preferably outputs control signals according to the flow rate of the liquid raw material flowing in the liquid raw material supply pipe 700, the flow rate of the carrier gas flowing in the carrier gas supply pipe 710, and the flow rate of the source gas flowing in the source gas supply pipe 720.

The film forming chamber 500 is formed in an approximately cylindrical shape. A susceptor 502, on which a wafer W is horizontally mounted, is disposed in an inner space defined by a ceiling wall 500A (made of. e.g., aluminum or stainless steel) and a bottom wall 500B of the film forming chamber 500. The susceptor 502 is supported by a plurality of cylindrical support members 504 (only one of the cylindrical support members is shown in FIG. 1). A heater 506 is embedded in the susceptor 502. The temperature of the wafer W mounted on the susceptor 502 can be adjusted by controlling power supplied from a power supply 508 to the heater 506.

A gas exhaust port 510 is formed at the bottom wall 500B of the film forming chamber 500. A gas exhaust system 512 is connected to the gas exhaust port 510. The inner pressure of the film forming chamber 500 can be reduced to a predetermined vacuum level by the gas exhaust system 512.

A shower head 514 is mounted to the ceiling wall 500A of the film forming chamber 500. The source gas supply pipe 720 is connected to the shower head 514. The source gas generated by vaporization of the vaporizer 401 is introduced into the shower head 514 via the source gas supply pipe 720. The shower head 514 includes an inner space 514A and a plurality of gas discharge holes 514B formed on a surface facing the susceptor 502. Consequently, the source gas, introduced into the inner space 514A of the shower head 514 via the source gas supply pipe 720, is discharged toward the wafer W mounted on the susceptor 502 through the gas discharge holes 514B.

In the film forming apparatus 100 in accordance with this embodiment, the liquid raw material supply source 200 stores, e.g., a hafnium-based organic metal compound as a liquid raw material. The liquid raw material is forwarded to the vaporizer 401 via the liquid raw material supply pipe 700. The hafnium-based organic metal compound may include, e.g., tetratertiarybutoxy hafnium [Hf (Ot-Bu)₄], tetradiethyl-amino hafnium [Hf (NEt₂)₄], tetrakismethoxymethylpropoxy hafnium [Hf(MMP)₄], tetradimethylamino hafnium [Hf (NMe₂)₄], tetramethylethylamino hafnium [Hf(NMeEt)₄], and tetrakis-triethylsiloxy hafnium [Hf(OSiEt₃)₄].

A non-hafnium-based organic metal compound may be used as a liquid raw material. The non-hafnium-based organic metal compound may include, e.g., pentaethoxy tantalum [Ta(O-Et)], tetratertiarybutoxy zirconium [Zr(Ot-Bu)₄], tetraethoxy silicon [Si(OEt)₄], tetradimethylamino silicon [Si(NMe₂)₄], tetrakismethoxymethylpropoxy zirconium [Zr(MMP)₄], bisethylcyclopentadienyl ruthenium [Ru(EtCp)₂], tertiaryamylimidetridimethylamide tantalum [Ta(Nt-Am)(NMe₂)₃], and trisdimethylamino silane [HSi(NMe₂)₃].

The organic metal compound is liquid or solid at room temperature. Consequently, when the organic metal compound is used as the liquid raw material, the organic metal compound is generally diluted or dissolved by an organic solvent, such as octane.

The vaporizer 401 of the film forming apparatus 100 is configured to discharge liquid droplets of the liquid raw material one by one from discharge ports disposed therein, vaporize the discharged liquid droplets, and forward the resultant source gas to the source gas supply pipe 720. The details of the vaporizer 401 will be described later. If the liquid raw material is not completely vaporized by the vaporizer 401, some of the liquid droplets of the liquid raw material may be forwarded to the source gas supply pipe 720, while being mixed with the source gas, and may reach the film forming chamber 500. The liquid droplets of the liquid raw material introduced into the film forming chamber 500 are particles which may deteriorate the film quality of a hafnium oxide film formed on the wafer W.

One of the causes of vaporization defects of the liquid raw material in the vaporizer 401 is the difference in size of liquid droplets of the liquid raw material introduced into the vaporizer 401. In particular, when large-sized liquid droplets are introduced into the vaporizer 401, they may not be completely vaporized in the vaporizer 401, and they may reach the film forming chamber 500. In this aspect, the vaporizer 401 of this embodiment is configured to form fine liquid droplets having a uniform size from the liquid raw material and reliably vaporize the liquid droplets, as will be described below.

(Vaporizer of First Embodiment)

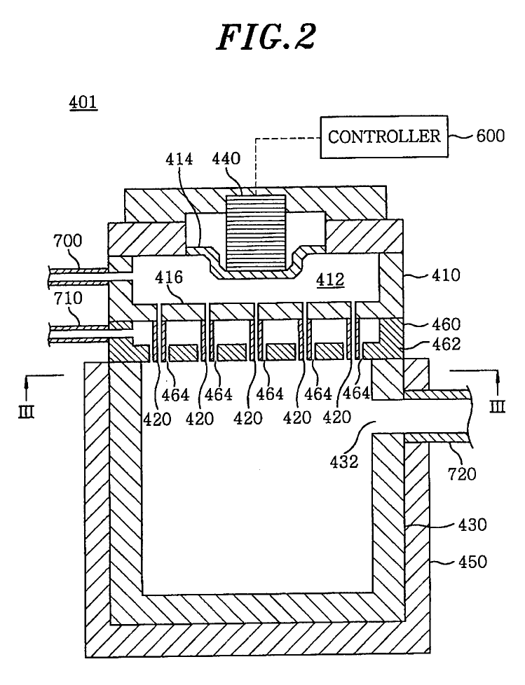

Next, a vaporizer in accordance with a first embodiment of the present invention will be described with reference to the drawings. FIG. 2 is a longitudinal cross sectional view illustrating a schematic configuration of a vaporizer 401 in accordance with a first embodiment of the present invention. As shown in FIG. 2, the vaporizer 401 includes a raw material liquid chamber 410 to which a liquid raw material is supplied and a vaporization chamber 430 for vaporizing liquid droplets of the liquid raw material discharged from the raw material liquid chamber 410. The liquid raw material from the liquid raw material supply source 200 is supplied at a predetermined pressure into an inner space 412 of the raw material liquid chamber 410 via the liquid raw material supply pipe 700.

A plurality of raw material discharge nozzles 420 are attached to a bottom portion 416 of the raw material liquid chamber 410 to discharge the liquid raw material from the inner space 412 of the raw material liquid chamber 410 into the vaporization chamber 430. A plurality of fine holes are formed at the bottom portion 416 of the raw material liquid chamber 410, and the fine holes communicate with through-holes of the respective raw material discharge nozzles 420, thereby forming liquid raw material discharge ports.

The respective raw material discharge nozzles 420 are arranged perpendicular to the bottom portion 416 of the raw material liquid chamber 410 such that the discharge directions of the liquid raw material from the respective raw material discharge nozzles 420 are parallel to one another. Further, the respective raw material discharge nozzles 420 are distributed in the plane direction perpendicular to the discharge direction of the liquid raw material. The detailed arrangement of the raw material discharge nozzles 420 will be described later.

Although the liquid raw material discharge ports of the raw material liquid chamber 410 in the first embodiment are described as being formed by the raw material discharge nozzles 420, the configuration thereof is not limited thereto. For example, a plate-shaped member having a plurality of through-holes may be attached to the bottom portion 416 of the raw material liquid chamber 410 such that the through-holes of the plate-shaped member communicate with the fine holes of the bottom portion 416 to form the liquid raw material discharge ports.

The diameter of the discharge ports of the raw material discharge nozzles 420 is basically determined according to the target size of liquid droplets of the liquid raw material discharged into the vaporization chamber 430. Specifically, it is preferable to determine the diameter of the discharge ports of the raw material discharge nozzles 420 from the following aspect. For example, it is preferable that the size of liquid droplets is small so as to reliably vaporize the liquid droplets in the vaporization chamber 430 and, thus, it is preferable that the diameter of the discharge ports of the raw material discharge nozzles 420 is small.

However, when the diameter of the discharge ports of the raw material discharge nozzles 420 is too small, the size of liquid droplets also becomes smaller. Accordingly, the flow rate of the source gas obtained by vaporizing the liquid droplets may be insufficient. Further, it may be difficult to discharge the liquid droplets from the respective raw material discharge nozzles 420 unless an excessive discharge pressure is applied to the liquid raw material in the inner space 412. In consideration of this aspect, the diameter of the discharge ports of the raw material discharge nozzles 420 is set to be, e.g., 20 μm.

Preferably, the raw material discharge nozzles 420 are made of metal such as stainless steel or titanium (Ti) or synthetic resin such as polyimide resin having resistance against an organic solvent. When the raw material discharge nozzles 420 are made of synthetic resin, it is possible to prevent heat from being transferred to the liquid raw material from the surroundings before the liquid raw material is discharged. Further, when the raw material discharge nozzles 420 are made of polyimide resin, the residues (solidified residues) of the liquid raw material are hardly attached to the raw material discharge nozzles 420, and it is possible to prevent the raw material discharge nozzles 420 from being clogged.

The vaporization chamber 430 vaporizes the liquid raw material discharged from the raw material discharge nozzles 420 to generate a source gas. The vaporization chamber 430 is formed in an approximately cylindrical shape in which the cross section of the vaporization chamber 430 perpendicular to the discharge direction of the liquid raw material is circular. Consequently, the wall of the vaporization chamber 430 is isotropic with respect to the liquid droplets discharged from the raw material discharge nozzles 420. Thus, it is possible to efficiently transfer heat to the liquid droplets from a heating unit 450 to be described later, and it is possible to achieve more stable vaporization of the raw material.

A source gas draining port 432 is formed at the sidewall of the vaporization chamber 430. The source gas supply pipe 720 is connected to the source gas draining port 432. Consequently, the source gas generated in the vaporization chamber 430 is supplied to the film forming chamber 500 via the source gas supply pipe 720.

The vaporization chamber 430 is provided with a heating unit 450, which is configured to cover the cylindrical sidewall and bottom of the vaporization chamber 430. It is possible to adjust the atmosphere in the vaporization chamber 430 to have a temperature appropriate for the vaporization of the liquid droplets of the liquid raw material by using the heating unit 450. Specifically, it is preferable to adjust the atmosphere in the vaporization chamber 430 to have a temperature higher than the vaporization temperature of the liquid raw material and lower than the decomposition temperature at which the liquid raw material is solidified. For example, a cartridge type or tape type resistance heater may be used as the heating unit 450.

In this embodiment, the raw material liquid chamber 410 is provided with a pressurizing unit for periodically changing the volume of the inner space 412 of the raw material liquid chamber 410 to apply a discharge pressure to the liquid raw material. The pressurizing unit may be formed as a vibration unit, e.g., a piezoelectric element 440, for vibrating a flexible member 414 which forms a portion of the walls of the raw material liquid chamber 410.

The flexible member 414 may be formed as, e.g., a diaphragm. Further, a member exhibiting vibration property or elasticity, such as rubber, resin or metal, may be employed as the flexible member 414.

Hereinafter, a configuration of discharging the liquid raw material from the raw material liquid chamber 410 through the discharge ports using the vibration of the piezoelectric element 440 will be described in more detail. The piezoelectric element 440 vibrates in an expansion and contraction manner, for example, in the thickness direction thereof according to a control signal (voltage) from the controller 600. The piezoelectric element 440 is disposed such that a vibratory part of the piezoelectric element 440 is in contact with the flexible member 414 of the raw material liquid chamber 410. Consequently, the vibration of the piezoelectric element 440 is transmitted to the flexible member 414, and the volume of the inner space 412 of the raw material liquid chamber 410 is changed by the vibration of the flexible member 414. For example, when the flexible member 414 is vibrated such that the flexible member 414 is bent toward the inner space 412 of the raw material liquid chamber 410 as shown in FIG. 2, the volume of the inner space 412 decreases and a discharge pressure equivalent to the bent amount of the flexible member 414 is applied to the liquid raw material in the inner space 412. Accordingly, the liquid raw material is ejected from the discharge ports of the respective raw material discharge nozzles 420.

The piezoelectric element 440 may be constructed, e.g., in a bimorph structure in which two piezoelectric materials are stacked, or in a stack structure in which a plurality of piezoelectric materials are stacked. When the piezoelectric element 440 has one of those structures, the piezoelectric element 440 can have a relatively large displacement in its thickness direction. Accordingly, it is possible to adjust the amplitude of the flexible member 414 within a wide range. Consequently, the size of liquid droplets discharged from the raw material discharge nozzles 420 can be adjusted within a wide range.

When the volume of the inner space 412 of the raw material liquid chamber 410 is periodically changed by using the pressurizing unit such as the piezoelectric element 440, as described above, it is possible to make uniform the discharge amount of the liquid droplets discharged from the respective discharge ports, and also possible make uniform the size of the liquid droplets discharged from the respective discharge ports in the discharge direction thereof. Further, the size of liquid droplets in the discharge direction thereof can be controlled to be further reduced by further shortening the volume changing period while reducing the change amount of the volume of the inner space of the raw material liquid chamber. Consequently, it is possible to discharge much finer liquid droplets having a uniform size from the discharge ports.

Further, as the vibration unit such as the piezoelectric element 440 is used as the pressurizing unit, the flexible member 414 vibrates and a discharge pressure is periodically applied to the liquid raw material in the raw material liquid chamber 410. Accordingly, the liquid raw material from the respective discharge ports can be efficiently formed into liquid droplets. Thus, it is possible to control the size of the liquid droplets in the discharge direction thereof to be further uniformized. Further, by controlling the vibration frequency and amplitude of voltage applied to the piezoelectric element 440, finer control of the size of the liquid droplets in the discharge direction thereof can be made.

As the diameters of the liquid droplets are controlled to be further minute and further uniform as described above, it is possible to surely vaporize the liquid droplets in the vaporization chamber 430. Consequently, it is possible to generate a source gas of good quality containing no particles. Further, as fine liquid droplets having a uniform size can be continuously discharged from the respective discharge ports, it is possible to generate a sufficient flow rate of the source gas.

Further, in this embodiment, in order to control the discharge direction of the liquid droplets discharged from the discharge ports of the respective raw material discharge nozzles 420, a carrier gas chamber 460 is disposed between the raw material liquid chamber 410 and the vaporization chamber 430, such that a carrier gas from the carrier gas chamber 460 is ejected in the same direction as the discharge direction of the liquid droplets from the circumferences of the respective discharge ports. Specifically, for example, as shown in FIG. 2, the raw material discharge nozzles 420 are disposed in a plurality of carrier gas ejection ports 464 formed at a bottom portion 462 of the carrier gas chamber 460.

A carrier gas is supplied into the carrier gas chamber 460 from the carrier gas supply source 300 via the carrier gas supply pipe 710, and is ejected from the respective carrier gas ejection ports 464. Consequently, the carrier gas, supplied into the carrier gas chamber 460, is uniformly distributed to the respective carrier gas ejection ports 464, and is ejected into the vaporization chamber 430. For example, a nonreactive gas, such as N₂, He or Ar, is preferably used as the carrier gas.

As the discharge ports of the respective raw material discharge nozzles 420 are disposed in the corresponding carrier gas ejection ports 464 as described above, it is possible to eject the carrier gas from the circumferences of the respective discharge ports. Accordingly, it is possible to stabilize the flight of the liquid droplets discharged into the vaporization chamber and to surely control the flight direction of the liquid droplets, thus enabling the liquid droplets to be vaporized without being combined with each other.

Further, as the raw material discharge nozzles 420 are disposed in the respective carrier gas ejection ports 464, it is possible to surely discharge the liquid raw material from the raw material liquid chamber 410 toward the vaporization chamber 430 even when the longitudinal dimension of the raw material discharge nozzles 420 is shortened. In particular, the vaporizer of this embodiment is configured such that the liquid raw material is discharged from the respective raw material discharge nozzles 420 by using the discharge pressure applied from the piezoelectric element 440. Consequently, when the longitudinal dimension of the raw material discharge nozzles 420 is short, it is possible to further efficiently transmit the discharge pressure to the discharge ports of the front ends of the respective raw material discharge nozzles 420.

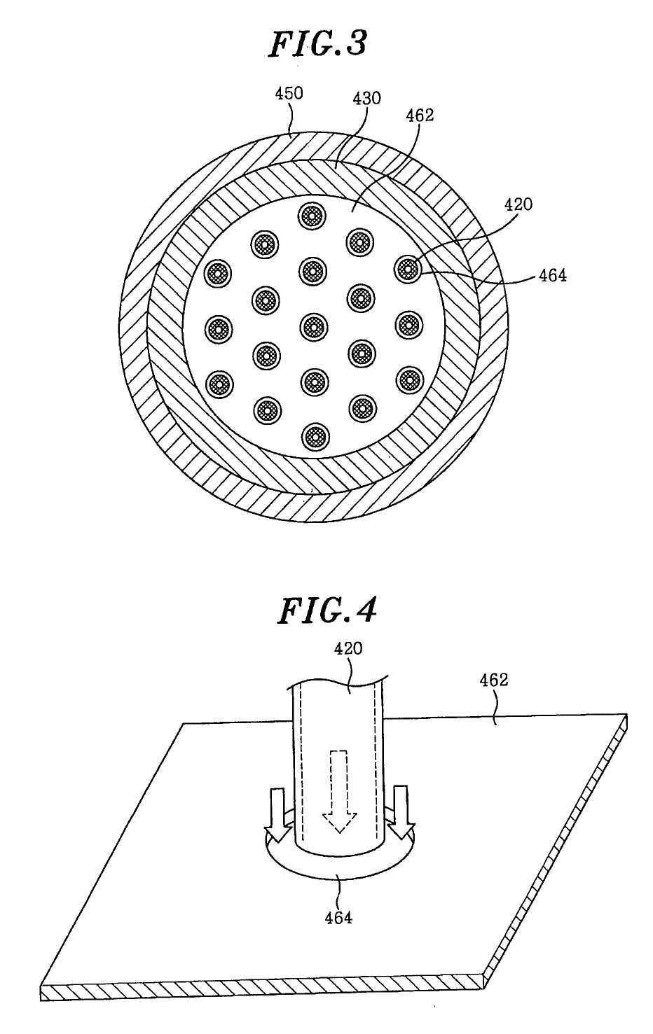

Hereinafter, an arrangement example of the respective raw material discharge nozzles 420 and the corresponding carrier gas ejection ports 464 in the plane direction perpendicular to the discharge direction of the liquid raw material will be described with reference to FIG. 3. FIG. 3 is a cross sectional view taken along line III-III of the vaporizer 401 shown in FIG. 2 when viewed in the direction indicated by arrows. As shown in FIG. 3, the number of the carrier gas ejection ports 464 is equal to that of the raw material discharge nozzles 420. The carrier gas ejection ports 464 have a diameter larger than that of the discharge ports of the raw material discharge nozzles 420. As described above, the discharge ports of the raw material discharge nozzles 420 are disposed in the carrier gas ejection ports 464, respectively. Further, the discharge ports of the raw material discharge nozzles 420 and the carrier gas ejection ports 464 are uniformly arranged over the whole area of the vaporization chamber 430 in the plane direction thereof. Consequently, it is possible to supply the liquid droplets discharged from the respective raw material discharge nozzles 420 over the whole area of the vaporization chamber 430 in the discharge direction of the respective liquid droplets.

Further, since the respective raw material discharge nozzles 420 are disposed in the corresponding carrier gas ejection ports 464, the distance between the respective raw material discharge nozzles 420 is increased by as much as that. Moreover, since the respective raw material discharge nozzles 420 are disposed such that the discharge directions of the liquid raw material are parallel to one another, it is possible to surely vaporize the respective liquid droplets while the liquid droplets do not combine with one another.

FIG. 4 is a perspective view illustrating an arrangement relationship between one of the raw material discharge nozzles 420 and the corresponding one of the carrier gas ejection ports 464 shown in FIG. 2. As shown in FIG. 4, the raw material discharge nozzle 420 is disposed such that the front end of the raw material discharge nozzle 420 is located at the center of the carrier gas ejection port 464. Consequently, a carrier gas can be efficiently ejected through the respective carrier gas ejection ports 464 around the entire circumferences of the discharge ports of the respective raw material discharge nozzles 420. Also, the flow direction of the carrier gas ejected from the respective carrier gas ejection ports 464 is adjusted, for example, to be parallel to the discharge direction of the liquid droplets discharged from the respective raw material discharge nozzles 420. In FIG. 4, the flow direction of the carrier gas is schematically indicated by solid-line arrows, and the flow direction of the liquid raw material is schematically indicated by a broken-line arrow.

As described above, the carrier gas flows in the discharge direction from the circumferences of the discharge ports of the respective raw material discharge nozzles 420. Accordingly, the respective liquid droplets of the liquid raw material discharged from the respective raw material discharge nozzles 420 can be surely dropped in the discharge direction. Consequently, it is possible to surely control the flight direction of the liquid droplets continuously discharged one by one and to stabilize the flight direction of the respective liquid droplets. Thus, it is possible to prevent the liquid droplets from combining with one another and to produce the fine liquid droplets. As a result, it is possible to further reliably vaporize the respective liquid droplets.

(Operation of Film Forming Apparatus)

The operation of the film forming apparatus 100 having the above configuration in accordance with this embodiment will be described with reference to FIGS. 1 and 2. In order to generate a source gas by the vaporizer 401, first, the raw material liquid chamber 410 of the vaporizer 401 is filled with a liquid raw material. That is, the opening degree of the liquid raw material flow rate control valve 702 is adjusted such that a predetermined amount of the liquid raw material is supplied from the liquid raw material supply source 200 into the raw material liquid chamber 410 via the liquid raw material supply pipe 700. At this time, it is preferable to adjust the opening degree of the carrier gas flow rate control valve 712 such that a predetermined amount of a carrier gas is supplied from the carrier gas supply source 300 into the carrier gas chamber 460 via the carrier gas supply pipe 710. Also, it is preferable to initiate the operation of the heating unit 450 so as to adjust the interior temperature of the vaporization chamber 430 to a predetermined level.

After the raw material liquid chamber 410 is filled with the liquid raw material, the vibrating operation of the piezoelectric element 440 is initiated to apply vibration to the flexible member 414 of the raw material liquid chamber 410. Upon the vibration of the flexible member 414, the volume of the inner space 412 of the raw material liquid chamber 410 is periodically changed, and the discharge pressure equivalent to the bent amount of the flexible member 414 is periodically applied to the liquid raw material in the inner space 412. Consequently, liquid droplets of the liquid raw material are continuously discharged from the respective raw material discharge nozzles 420 into the vaporization chamber 430.

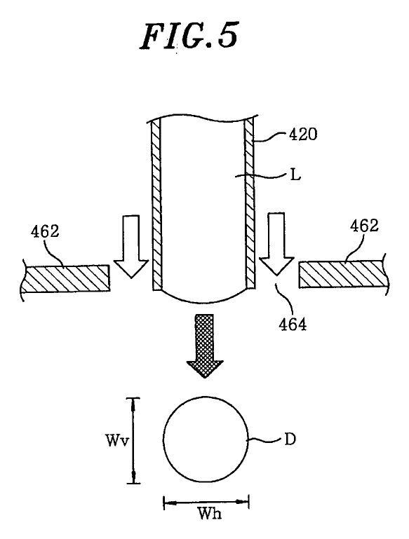

FIG. 5 is a conceptional view illustrating a state when a liquid droplet D is separated from a liquid raw material L in one of the raw material discharge nozzles 420 and is discharged from the front end of the raw material discharge nozzle 420 in the vaporizer 401 in accordance with the first embodiment. In FIG. 5, the flow direction of a carrier gas is schematically indicated by white arrows, and the flight direction of the liquid droplet D is schematically indicated by a hatched arrow. As shown in FIG. 5, the liquid droplet D discharged from the raw material discharge nozzle 420 is applied with a propulsive force from the carrier gas ejected from the surrounding carrier gas ejection port 464. Accordingly, the liquid droplet D moves in the vaporization chamber 430 in the longitudinal direction of the raw material discharge nozzle 420.

The horizontal width Wh of the liquid droplet D discharged from the raw material discharge nozzle 420 is defined by the inner diameter of the raw material discharge nozzle 420. As described above, the discharge port of the raw material discharge nozzle 420 in accordance with this embodiment is very small. For example, the discharge port of the raw material discharge nozzle 420 has a diameter of 20 μm. Consequently, the horizontal width Wh of the liquid droplet D is about 20 μm. On the other hand, the vertical width Wv of the liquid droplet D is determined according to the amount of the liquid raw material ejected from the raw material discharge nozzle 420. The amount of the liquid raw material may be adjusted by the bent amount of the flexible member 414 of the raw material liquid chamber 410, i.e., the amplitude (displacement amount) of the piezoelectric element 440. In this embodiment, therefore, voltage applied to the piezoelectric element 440 is controlled to adjust the amplitude of the piezoelectric element 440 such that the vertical width Wv of the liquid droplet D is set to be, e.g., 20 μm. Consequently, it is possible to form a fine liquid droplet D having the horizontal width Wh and the vertical width Wv which are adjusted to be very small.

Further, in this embodiment, a plurality of the raw material discharge nozzles 420 are disposed in the vaporizer 401 and, thus, it is possible to discharge the same number of liquid droplets D as the raw material discharge nozzles 420 at one time. Consequently, it is possible to generate a sufficient amount of a source gas by vaporizing a plurality of the liquid droplets D in the vaporization chamber 430 even though the liquid droplets D are micro-sized.

Further, the flow rate of the source gas may be adjusted by controlling the vibration frequency of the piezoelectric element 440. For example, when the vibration frequency of the piezoelectric element 440 is increased, the number of liquid droplets discharged from the respective raw material discharge nozzles 420 per unit time increases, thereby increasing the flow rate of the source gas. When controlling the vibration frequency of the piezoelectric element 440, it is necessary to consider the natural frequency of the piezoelectric element 440. For example, it is preferable to control the vibration frequency of the piezoelectric element 440 to be one third or less of the natural frequency of the piezoelectric element 440.

The fine liquid droplets discharged from the respective raw material discharge nozzles 420 one by one come into contact with the atmosphere in the vaporization chamber 430 adjusted to have a predetermined temperature. Accordingly, the liquid droplets are vaporized into a source gas while flying in the vaporization chamber 430. The generated source gas is forwarded from the source gas draining port 432, formed at the wall of the vaporization chamber 430, to the film forming chamber 500 via the source gas supply pipe 720. Further, the flow rate of the source gas to be introduced into the film forming chamber 500 may be adjusted by controlling the opening degree of the source gas flow rate control valve 722 provided at the source gas supply pipe 720.

The source gas, forwarded to the film forming chamber 500, is introduced into the inner space 514A of the shower head 514 and is then discharged toward the wafer W on the susceptor 502 from the gas discharge holes 514B. Then, a predetermined film, e.g., a film containing an organic metal compound, is formed on the wafer W.

As described above, in the vaporizer 401 in accordance with the first embodiment, it is possible to discharge fine liquid droplets from the respective raw material discharge nozzles 420 into the vaporization chamber 430. Therefore, it is possible to surely vaporize all of the liquid droplets. Consequently, it is possible to supply a source gas of good quality containing no particles into the film forming chamber 500.

Further, it is possible to continuously discharge fine liquid droplets from the raw material discharge nozzles 420 and, thus, it is possible to stably generate an amount of a source gas required to perform a film forming process in the film forming chamber 500. Also, a plurality of liquid droplets discharged from the respective raw material discharge nozzles 420 do not combine into large-sized liquid droplets in the vaporization chamber 430, thereby surely vaporizing the liquid droplets.

Also, since the liquid droplets discharged into the vaporization chamber 430 are fine, the liquid droplets are vaporized without flying in the vaporization chamber 430 for a long time. Consequently, it is possible to reduce the longitudinal size of the vaporization chamber 430, thereby reducing the size of the vaporizer 401.

When the flow rate of the liquid raw material supplied from the liquid raw material supply source 200 into the raw material liquid chamber 410 is too large, an excessive pressure is applied to the liquid raw material in the raw material liquid chamber 410. Accordingly, the vertical width Wv of the liquid droplet D, which is adjusted by the amplitude of the piezoelectric element 440, may increase. On the other hand, when the flow rate of the liquid raw material is too small, the raw material liquid chamber 410 is partially empty. Accordingly, the vertical widths Wv of the liquid droplets D discharged from the respective raw material discharge nozzles 420 may differ from one another. Consequently, it is preferable to adjust the flow rate of the liquid raw material supplied from the liquid raw material supply source 200 into the raw material liquid chamber 410 based on the number of the liquid droplets discharged from the respective raw material discharge nozzles 420 per unit time and the size of the liquid droplets, i.e., the amplitude and vibration frequency of the piezoelectric element 440.

(Vaporizer of Second Embodiment)

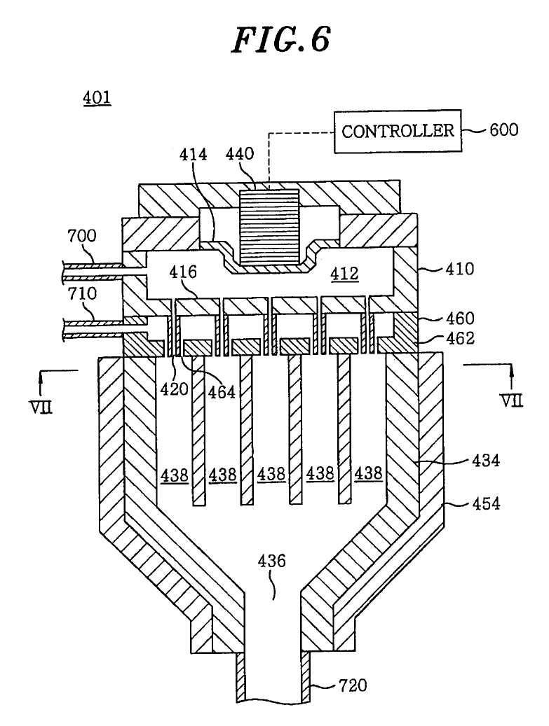

Hereinafter, a vaporizer in accordance with a second embodiment of the present invention will be described with reference to the drawings. FIG. 6 is a longitudinal cross sectional view illustrating a schematic configuration of a vaporizer 402 in accordance with a second embodiment of the present invention. In the first embodiment, the source gas draining port 432 is formed at the sidewall of the vaporization chamber 430. However, in the second embodiment, a source gas draining port 436 is formed at a bottom portion of a vaporization chamber 434, which will be described below. Further, a raw material liquid chamber 410, raw material discharge nozzles 420, a piezoelectric element (pressurizing unit or vibration unit) 440 and a carrier gas chamber 460 are identical to those of the first embodiment and, thus, a detailed description thereof will not be given.

The vaporization chamber 434 in accordance with the second embodiment is configured in an approximately cylindrical shape, and the bottom portion of the vaporization chamber 434 is formed such that the cross sectional diameter of the bottom portion gradually decreases toward the source gas draining port 436. A source gas supply pipe 720 is connected to the source gas draining port 436. A source gas generated in the vaporization chamber 434 is introduced into a film forming chamber 500 via the source gas supply pipe 720.

Further, the vaporization chamber 434 is provided with a plurality of guide holes 438 for guiding liquid droplets of a liquid raw material discharged from the respective raw material discharge nozzles 420 to the source gas draining port 436. The inlets of the guide holes 438 face discharge ports of the raw material discharge nozzles 420 and the carrier gas ejection ports 464, respectively.

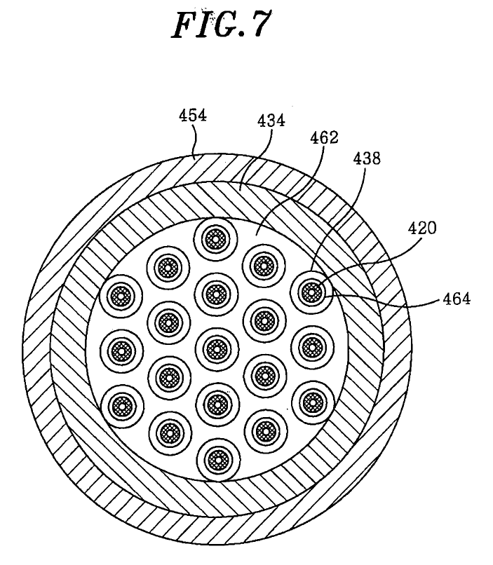

Next, a positional relationship among the raw material discharge nozzles 420, the carrier gas ejection ports 464, and the guide holes 438 in the plane direction perpendicular to the discharge direction of the liquid raw material will be described with reference to the drawings. FIG. 7 is a cross sectional view taken along line VII-VII of the vaporizer 402 shown in FIG. 6. As shown in FIG. 7, the number of the raw material discharge nozzles 420, the number of the carrier gas ejection ports 464, and the number of the guide holes 438 are the same. Also, the raw material discharge nozzles 420, the carrier gas ejection ports 464, and the guide holes 438 are uniformly arranged over the whole area of the vaporization chamber 434 in the plane direction thereof.

As described above, the guide holes 438 are provided to face the carrier gas ejection ports 464 in which the raw material discharge nozzles 420 are disposed, respectively. Accordingly, the liquid droplets of the liquid raw material discharged from the respective raw material discharge nozzles 420 can be surely introduced into the corresponding guide holes 438 one by one along with the carrier gas ejected from the respective carrier gas ejection ports 464. Further, the liquid droplets discharged from the raw material discharge nozzles 420 can move along the guide holes 438, respectively, while the liquid droplets discharged from the raw material discharge nozzles 420 are not mixed with each other. Consequently, it is possible to further improve the vaporization efficiency of the liquid droplets of the liquid raw material discharged from the respective raw material discharge nozzles 420.

The vaporization chamber 434 is provided with a heating unit 454, which is configured to cover the cylindrical sidewall and bottom of the vaporization chamber 434. It is possible to adjust the atmosphere in the vaporization chamber 434, particularly in the respective guide holes 438, to a temperature appropriate for the vaporization of the liquid droplets of the liquid raw material by using the heating unit 454. Specifically, it is preferable to adjust the atmosphere in the vaporization chamber 434 to a temperature higher than the vaporization temperature of the liquid raw material and lower than the decomposition temperature at which the liquid raw material is solidified. For example, a cartridge type or tape type resistance heater may be used as the heating unit 454.

As described above, in the vaporizer 402 in accordance with the second embodiment, it is possible to surely vaporize the liquid droplets in the respective guide holes 438 one by one. Further, a plurality of the liquid droplets simultaneously discharged from a plurality of the raw material discharge nozzles 420 are individually forwarded into the respective guide holes 438. Accordingly, the liquid droplets are prevented from combining with one another. As a result, since large-sized liquid droplets do not exist in the vaporization chamber 434, it is possible to completely prevent the vaporization defect of the liquid droplets. Consequently, it is possible to supply a source gas of good quality containing no particles into the film forming chamber 500.

Also, since the carrier gas is introduced into the guide holes 438 along with the liquid droplets, it is possible to vaporize the liquid droplets introduced into the respective guide holes 438 while the liquid droplets are not in contact with the inner walls of the respective guide holes 438. Consequently, it is possible to prevent the liquid droplets from being attached to the inner walls of the respective guide holes 438 and, thus, it is also possible to prevent the generation of particles resulting from the thermal decomposition of the liquid droplets.

(Vaporizer of Third Embodiment)

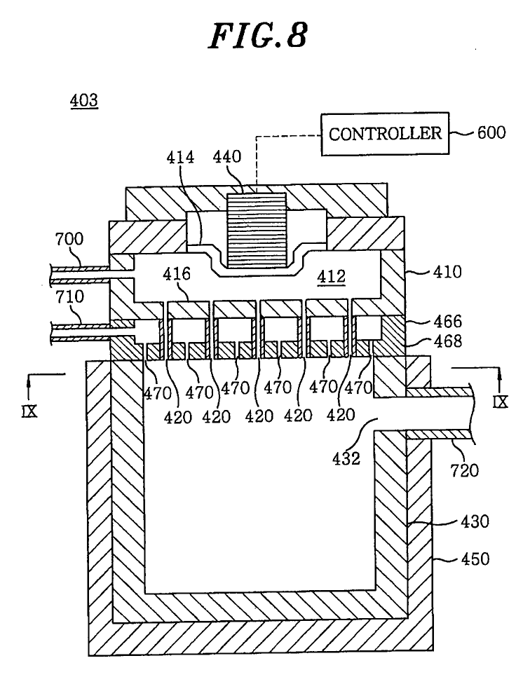

Hereinafter, a vaporizer in accordance with a third embodiment of the present invention will be described with reference to the drawings. FIG. 8 is a longitudinal cross sectional view illustrating a schematic configuration of a vaporizer 403 in accordance with the third embodiment of the present invention. In the first embodiment, the discharge ports of the raw material discharge nozzles 420 are disposed in the respective carrier gas ejection ports 464. However, in the third embodiment, a plurality of carrier gas ejection ports 470 are disposed around discharge ports of raw material discharge nozzles 420, which will be described below. Also, a raw material liquid chamber 410, raw material discharge nozzles 420, a vaporization chamber 430, a piezoelectric element (pressurizing unit or vibration unit) 440 and a heating unit 450 are identical to those of the first embodiment and, therefore, a detailed description thereof will not be given.

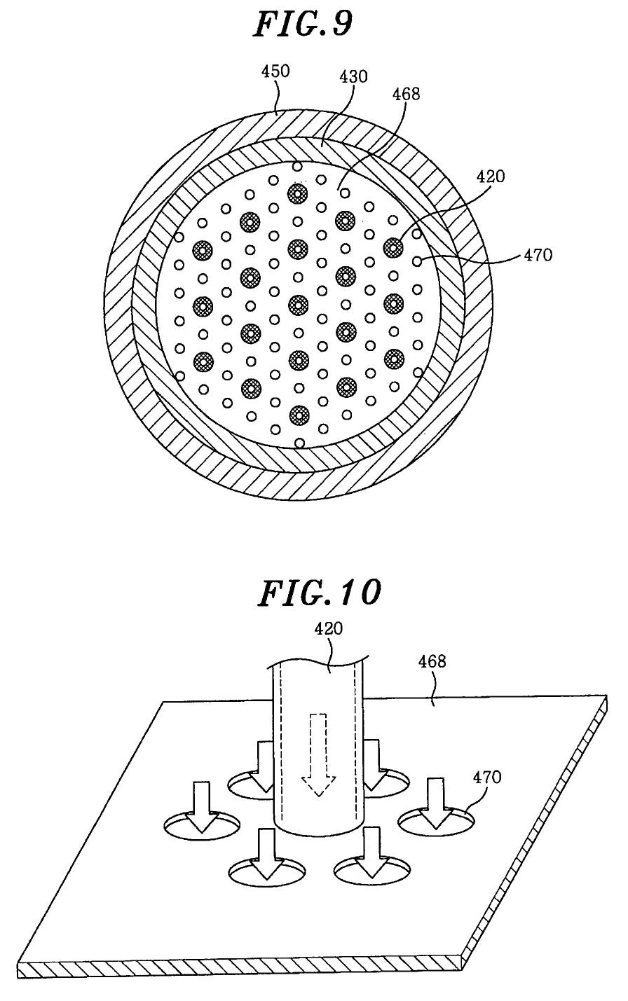

In the third embodiment, the carrier gas ejection ports 470 of a carrier gas chamber 466 are formed, for example, at a bottom portion 468 of the carrier gas chamber 466, as shown in FIG. 8. The carrier gas ejection ports 470 are disposed around the discharge ports of the respective raw material discharge nozzles 420. An arrangement example of the discharge ports of the respective raw material discharge nozzles 420 and the carrier gas ejection ports 470 is shown in FIG. 9. FIG. 9 is a cross sectional view taken along the line IX-IX of the vaporizer 403 shown in FIG. 8 when viewed in the direction indicated by arrows.

As shown in FIG. 9, the number of the carrier gas ejection ports 470 is greater than that of the raw material discharge nozzles 420. A plurality (e.g., six) of the carrier gas ejection ports 470 are disposed around the discharge port of each of the raw material discharge nozzles 420. Consequently, liquid droplets discharged from the raw material discharge nozzles 420 move along with a carrier gas ejected from the carrier gas ejection ports 470 around the raw material discharge nozzles 420. Therefore, it is possible to surely control the flight direction of the liquid droplets. Also, since a plurality of the carrier gas ejection ports 470 are disposed around the discharge port of each the raw material discharge nozzles 420, it is possible to increase the distance between the respective raw material discharge nozzles 420. Consequently, it is possible to prevent the liquid droplets from combining with one another and, therefore, it is possible to reliably vaporize the liquid droplets one by one.

FIG. 10 is a perspective view illustrating an arrangement relationship between one of the raw material discharge nozzles 420 and the carrier gas ejection ports 470 located around the raw material discharge nozzle 420 shown in FIG. 8. As shown in FIG. 10, a plurality (in this embodiment, six) of the carrier gas ejection ports 470 are located around each of the raw material discharge nozzles 420. Consequently, a carrier gas can be ejected through the respective carrier gas ejection ports 470 from the circumferences of the respective raw material discharge nozzles 420. Also, the flow direction of the carrier gas ejected from the respective carrier gas ejection ports 470 is adjusted, for example, to be parallel to the discharge direction of the liquid droplets discharged from the respective raw material discharge nozzles 420. In FIG. 10, the flow direction of the carrier gas is schematically indicated by solid-line arrows, and the flow direction of the liquid raw material is schematically indicated by a broken-line arrow.

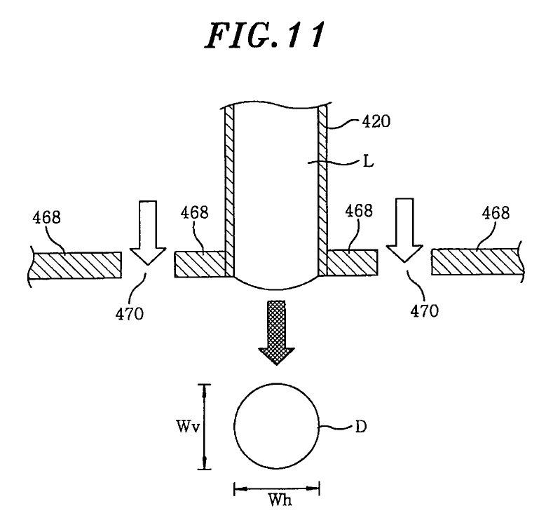

FIG. 11 is a conceptional view illustrating a state when a liquid droplet D is separated from a liquid raw material L in one of the raw material discharge nozzles 420 and is discharged from the front end of the raw material discharge nozzle 420 in the vaporizer 403 in accordance with the third embodiment. In FIG. 11, the flow direction of a carrier gas is schematically indicated by white arrows, and the flight direction of the liquid droplet D is schematically indicated by a hatched arrow. As shown in FIG. 11, the liquid droplet D discharged from the raw material discharge nozzle 420 moves in the vaporization chamber 430 in the longitudinal direction of the raw material discharge nozzle 420 by the carrier gas ejected from the surrounding carrier gas ejection ports 470.

It is possible to move the respective liquid droplets of the liquid raw material discharged from the respective raw material discharge nozzles 420 in the longitudinal direction thereof by forming the flow of the carrier gas around the discharge ports of the respective raw material discharge nozzles 420, as described above. Consequently, it is possible to stabilize the flight direction of the respective liquid droplets. Thus, it is possible to prevent the liquid droplets from combining with one another and to produce the fine liquid droplets. As a result, it is possible to further reliably vaporize the respective liquid droplets.

Also in the vaporizer 403 in accordance with the third embodiment as described above, it is possible to discharge fine liquid droplets from the respective raw material discharge nozzles 420 into the vaporization chamber 430 and, thus, it is possible to reliably vaporize all of the liquid droplets, as in the first and second embodiments. Consequently, it is possible to supply a source gas of good quality containing no particles into the film forming chamber 500.

Also, it is possible to continuously discharge fine liquid droplets from the raw material discharge nozzles 420 and, therefore, it is possible to stably generate an amount of a source gas required to perform a film forming process in the film forming chamber 500. Also, a plurality of liquid droplets discharged from the respective raw material discharge nozzles 420 do not combine into large-sized liquid droplets in the vaporization chamber 430. Thus, it is possible to reliably vaporize the liquid droplets.

Also, since the liquid droplets discharged into the vaporization chamber 430 are micro-sized, the liquid droplets are vaporized without flying in the vaporization chamber 430 for a long time. Consequently, it is possible to reduce the longitudinal size of the vaporization chamber 430, thereby reducing the size of the vaporizer 401.

While the invention has been shown and described with respect to the embodiments, it will be understood by those skilled in the art that various changes and modification may be made without departing from the scope of the invention as defined in the following claims.

For example, the film forming process may be performed using several kinds of source gases although only one kind of source gas was used in the first to third embodiments. In this case, a plurality of raw material supply systems may be provided, and a plurality of liquid raw materials supplied from the raw material supply systems may be mixed and supplied to the vaporizer. Also, a plurality of vaporizers may be provided, and the vaporizers may be exclusively used for the respective liquid raw materials.

Further, although the vaporizer used for the film forming apparatus was described in the first to third embodiments, the present invention is not limited thereto. For example, the present invention may be applied to vaporizers used in other different apparatuses, such as a metal-organic CVD (MOCVD) apparatus, a plasma CVD apparatus, an atomic layer deposition (ALD) apparatus or the like.

While the invention has been shown and described with respect to the embodiments, it will be understood by those skilled in the art that various changes and modification may be made without departing from the scope of the invention as defined in the following claims.

### INDUSTRIAL APPLICABILITY

The present invention is applicable to a vaporizer for vaporizing a liquid raw material to generate a source gas and a film forming apparatus including the vaporizer.

What is claimed is:

1. A vaporizer comprising:
a raw material liquid chamber into which a liquid raw material is supplied at a predetermined pressure;
raw material discharge nozzles configured to protrude from the raw material liquid chamber and to discharge the liquid raw material stored in the raw material liquid chamber;
carrier gas ejection ports configured to surround discharge ports of the raw material discharge nozzles and to eject a carrier gas;
a vaporization chamber for vaporizing the liquid raw material discharged from the discharge ports of the raw material discharge nozzles to generate a source gas; and
a pressurizing unit for periodically changing a volume of an inner space of the raw material liquid chamber to apply a discharge pressure to the liquid raw material.

2. The vaporizer of claim 1, wherein a diameter of each of the discharge ports is set according to a target size of liquid droplets of the liquid raw material discharged into the vaporization chamber.

3. The vaporizer of claim 2, wherein the diameter of the discharge ports is 20 μm or less.

4. The vaporizer of claim 1, wherein the discharge ports are disposed such that discharge directions of the liquid raw material are parallel to one another, and are uniformly arranged in a plane direction perpendicular to the discharge directions of the liquid raw material.

5. The vaporizer of claim 4, wherein an area where the discharge ports are arranged is set according to an area of the vaporization chamber in the plane direction.

6. A vaporizer comprising:
a raw material liquid chamber into which a liquid raw material is supplied at a predetermined pressure;
raw material discharge nozzles configured to protrude from the raw material liquid chamber and to discharge the liquid raw material stored in the raw material liquid chamber;
carrier gas ejection ports configured to surround discharge ports of the raw material discharge nozzles and to eject a carrier gas;
a vaporization chamber for vaporizing the liquid raw material discharged from the discharge ports of the raw material discharge nozzles to generate a source gas;
a flexible member forming a portion of a wall of the raw material liquid chamber; and
a vibration unit for vibrating the flexible member to apply a periodic discharge pressure to the liquid raw material in the raw material liquid chamber.

7. The vaporizer of claim 6, wherein the vibration unit includes a piezoelectric element.

8. The vaporizer of claim 6, wherein an amplitude of the vibration unit is set according to the number of the raw material discharge nozzles and a target size of liquid droplets of the liquid raw material discharged into the vaporization chamber.

9. The vaporizer of claim 6, wherein a vibration period of the vibration unit is set according to a target number of liquid droplets of the liquid raw material discharged into the vaporization chamber per unit time.

10. The vaporizer of claim 1, wherein the number of the carrier gas ejection ports is equal to that of the discharge ports, and a diameter of the carrier gas ejection ports is greater than that of the discharge ports such that the discharge ports are disposed in the carrier gas ejection ports, respectively.

11. The vaporizer of claim 1, wherein the number of the carrier gas ejection ports is greater than that of the discharge ports such that a plurality of the carrier gas ejection ports are disposed around each of the discharge ports.

12. A vaporizer comprising:
a raw material liquid chamber into which a liquid raw material is supplied at a predetermined pressure;
raw material discharge nozzles configured to protrude from the raw material liquid chamber and to discharge the liquid raw material stored in the raw material liquid chamber;
carrier gas ejection ports configured to surround discharge ports of the raw material discharge nozzles and to eject a carrier gas;
a vaporization chamber for vaporizing the liquid raw material discharged from the discharge ports of the raw material discharge nozzles to generate a source gas;
a pressurizing unit for periodically changing a volume of an inner space of the raw material liquid chamber to apply a discharge pressure to the liquid raw material; and
a draining port for draining the source gas from the vaporization chamber,
wherein the vaporization chamber has guide holes for guiding liquid droplets of the liquid raw material discharged from the discharge ports toward the draining port, and
wherein inlets of the guide holes face the discharge ports, respectively.

13. A film forming apparatus comprising:
a raw material supply system for supplying a liquid raw material;
a vaporizer for vaporizing the liquid raw material to generate a source gas; and
a film forming chamber into which the source gas is introduced from the vaporizer, the film forming chamber being configured to perform a film forming process on a substrate to be processed,
wherein the vaporizer includes:
a raw material liquid chamber into which a liquid raw material is supplied at a predetermined pressure;
raw material discharge nozzles configured to protrude from the raw material liquid chamber and to discharge the liquid raw material stored in the raw material liquid chamber;
carrier gas ejection ports configured to surround discharge ports of the raw material discharge nozzles and to eject a carrier gas to circumferences of the discharge ports;
a vaporization chamber for vaporizing the liquid raw material discharged from the discharge ports of the raw material discharge nozzles to generate a source gas; and
a pressurizing unit for periodically changing a volume of an inner space of the raw material liquid chamber to apply a discharge pressure to the liquid raw material.
